(19) United States
(12) Patent Application Publication
(10) Pub. No.: US 2009/0191651 A1
(43) Pub. Date: Jul. 30, 2009

(54) POSITIONING APPARATUS, EXPOSURE APPARATUS, AND METHOD OF MANUFACTURING DEVICE

(75) Inventor: Shinichi Egashira, Utsunomiya-shi (JP)

Correspondence Address: Locke Lord Bissell & Liddell LLP;Attn: IP Docketing, Three World Financial Center, New York, NY, 10281-2101, US

(73) Assignee: CANON KABUSHIKI KAISHA, Tokyo (JP)

(21) Appl. No.: 12/357,775

(22) Filed: Jan. 22, 2009

(30) Foreign Application Priority Data
Jan. 24, 2008 (JP) 2008-014174

(51) Int. Cl. H01L 21/66; G05D 1/00

(52) U.S. Cl. 438/16; 700/302; 257/E21.53; 250/492.2

(57) ABSTRACT

A positioning apparatus comprises a detector which detects the mark and outputs a mark signal and a controller. The controller includes a calculating unit which calculates position data of the mark based on the mark signal, a processing unit which calculates a parameter representing a displacement of the object, based on the mark signal and the position data of the mark, and a positioning controller which controls the positioning of the object, based on the position information of the object corrected by using the parameter calculated by said processing unit. The processing unit calculates a feature value, calculates a degree of influence that the feature value exerts on a displacement of the mark, corrects the calculated position data of the mark based on the calculated degree of influence, and statistically calculates the corrected position data of the mark, thereby calculating a parameter representing a displacement of the object.

### BACKGROUND OF THE INVENTION

1. Field of the Invention

The present invention relates to a positioning apparatus, an exposure apparatus, and a method of manufacturing a device.

2. Description of the Related Art

Along with advance in micropatterning and an increase in packing density of circuits, an exposure apparatus for use in the manufacture of a semiconductor device is required to be able to projection-expose a wafer surface so that a circuit pattern on a reticle surface is transferred onto the wafer surface with a higher resolving power. The resolving power of the circuit pattern depends on the exposure wavelength and the numerical aperture (NA) of the projection optical system, so a method of shortening the exposure wavelength and a method of increasing the NA of the projection optical system are adopted to improve the resolution. To shorten the exposure wavelength, the exposure light sources are shifting from the g-line to the i-line and even from the i-line to excimer lasers. Exposure apparatuses which use excimer lasers having oscillation wavelengths of 248 nm and 193 nm have already been put to practical use. Currently, an EUV exposure scheme which uses a wavelength of 13 nm is under study as a candidate for the next-generation exposure scheme.

Various forms of a process of manufacturing a semiconductor device have become available. The CMP (Chemical Mechanical Polishing) process and the like are attracting a great deal of attention as planarizing techniques which can prevent a decrease in the depth of focus of the exposure apparatus. A wide variety of structures and materials of semiconductor devices have also become available. For example, the following proposals have been made.

P-HEMTs (Pseudomorphic High Electron Mobility Transistors) formed by combining compounds such as GaAs and InP

M-HEMTs (Metamorphe-HEMTs)

HBTs (Heterojunction Bipolar Transistors) formed by using, for example, SiGe and SiGeC

Along with miniaturization of circuit patterns, it is also demanded to align a reticle on which a circuit pattern is formed and a wafer onto which it is to be projected, with an accuracy as high as ⅓ of the circuit line width. For example, a typical current circuit designed to have a line width of 90 nm must be aligned with an accuracy of ⅓ of 90 nm, that is, 30 nm.

Unfortunately, a wafer induced shift attributed to the manufacturing process often occurs upon wafer alignment, leading to deterioration in performance and a decrease in manufacturing yield of a semiconductor device. In this specification, a wafer induced shift will be abbreviated as a “WIS”. Examples of the WIS are asymmetries of the structure of an alignment mark and the shape of a resist applied on a wafer, due to the influence of a planarizing process in, for example, the CMP process. Furthermore, because a semiconductor device is manufactured by a plurality of processes, optical conditions such as the reflectance of the alignment mark and the resist surface shape change in each process, resulting in a process-specific variation in the amount of WIS. To cope with this problem, a plurality of alignment parameters are prepared to determine a process-specific optimal alignment parameter in the conventional wafer alignment. However, the determination of an optimal alignment parameter is time-consuming because wafer exposure and overlay inspection must be performed by actually using several alignment parameters. Japanese Patent Laid-Open No. 2003-203846 discloses an alignment method which eliminates the influence of any WIS without optimizing an alignment parameter by correcting the WIS on the basis of the alignment result using feature values obtained by quantifying the asymmetry and contrast of an alignment mark signal.

The alignment method described in Japanese Patent Laid-Open No. 2003-203846 individually uses various types of feature values as the correction values. However, the amount of WIS that is actually problematic in the manufacturing floor of a device intricately changes upon the mutual action among various types of feature values. Therefore, the method which individually uses various types of feature values as the correction values cannot accurately correct the WIS.

### SUMMARY OF THE INVENTION

The present invention has been made in consideration of the above-described problem of the prior art, and has as its object to provide a positioning apparatus which is applicable to, for example, an exposure apparatus, and positions an object by accurately correcting any WIS, that occurs in the manufacturing floor of a device, without optimizing an alignment parameter.

According to the first aspect of the present invention, there is provided a positioning apparatus which positions an object using a mark formed on the object, the apparatus comprising a detector which detects the mark and outputs a mark signal and a controller, the controller including a calculating unit which calculates position data of the mark on the basis of the mark signal output from the detector, a processing unit which calculates a parameter representing a displacement of the object, on the basis of the mark signal output from the detector and the position data of the mark calculated by the calculating unit, and a positioning controller which controls the positioning of the object, on the basis of the position information of the object corrected by using the parameter calculated by the processing unit, wherein the processing unit calculates a feature value including a value representing an asymmetry of the mark signal, a value representing a contrast of the mark signal, and a value representing a shape of the mark signal, calculates, on the basis of the calculated feature value, a degree of influence that the feature value exerts on a displacement of the mark calculated based on the calculation result obtained by the calculating unit, corrects the calculated position data of the mark on the basis of the calculated degree of influence, and statistically calculates the corrected position data of the mark, thereby calculating a parameter representing a displacement of the object.

According to the second aspect of the present invention, there is provided a positioning apparatus which positions an object using a mark formed on the object, the apparatus comprising a detector which detects the mark and outputs a mark signal and a controller, the controller including a calculating unit which calculates position data of the mark on the basis of the mark signal output from the detector, a processing unit which calculates a parameter representing a displacement of the object, on the basis of the mark signal output from the detector and the position data of the mark calculated by the calculating unit, and a positioning controller which controls the positioning of the object, wherein the processing unit calculates a feature value including a value representing an asymmetry of the mark signal, a value representing a contrast of the mark signal, and a value representing a shape of the mark signal, calculates, on the basis of the calculated feature value, a degree of influence that the feature value exerts on a displacement of the mark calculated based on the calculation result obtained by the calculating unit, statistically calculates the position data of the mark calculated by the calculating unit, thereby calculating a parameter representing a displacement of the object, statistically calculates the calculated degree of influence, thereby calculating a degree of influence that the feature value exerts on the parameter representing the displacement of the object, and corrects the calculated parameter using the calculated degree of influence exerted on the parameter, and the positioning controller controls the positioning of the object, on the basis of the position information of the object corrected by using the parameter corrected by the processing unit.

According to the present invention, it is possible to provide a positioning apparatus which is applicable to, for example, an exposure apparatus, and positions an object by accurately correcting any WIS, that occurs in the manufacturing floor of a device, without optimizing an alignment parameter.

Further features of the present invention will become apparent from the following description of exemplary embodiments with reference to the attached drawings.

### BRIEF DESCRIPTION OF THE DRAWINGS

FIG. 1 is a view schematically showing an exposure apparatus according to the present invention;

FIG. 2 is a view showing an alignment detection optical system applied to the apparatus shown in FIG. 1;

FIG. 3 is a view showing an example of the structure of a position detection mark applied to the apparatus shown in FIG. 1;

FIG. 4 is a view showing an example of mark signals obtained by marks shown in FIG. 3;

FIG. 5 is an explanatory diagram of a mark feature value;

FIG. 6 is an explanatory diagram of the mark feature value;

FIG. 7 is an explanatory diagram of the mark feature value;

FIG. 8 is an explanatory graph of the mark feature value;

FIG. 9 is an explanatory diagram of global alignment;

FIG. 10 is a flowchart illustrating an alignment process according to the first embodiment; and

FIG. 11 is a flowchart illustrating an alignment process according to the second embodiment.

### DESCRIPTION OF THE EMBODIMENTS

Preferred embodiments of the present invention will be described below with reference to the accompanying drawings. In the following description, an original, mask, and reticle will be generally referred to as a “reticle”, and a substrate and wafer will be generally referred to as a “substrate”. In addition, an alignment mark will be simply referred to as a “mark” hereinafter.

### First Embodiment

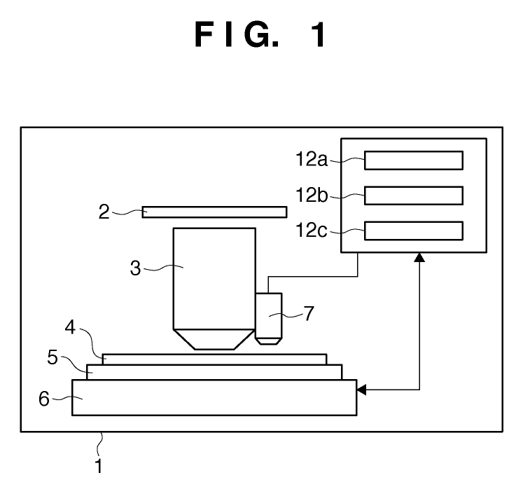

In the first embodiment, an exemplary positioning apparatus according to the present invention is applied to an exposure apparatus. FIG. 1 is a schematic view showing an exposure apparatus according to the present invention.

An exposure apparatus 1 includes a projection optical system 3 for projecting the pattern of a reticle 2, a substrate chuck 5 for holding a substrate 4, and a substrate stage 6 for moving the substrate 4 to position it at a predetermined position. The exposure apparatus 1 also includes an alignment detection optical system 7 serving as a detector which detects a mark formed on the substrate 4 and outputs a mark signal.

The exposure apparatus 1 includes a controller 12 including a calculating unit 12a, processing unit 12b, and control unit 12c. The calculating unit 12a calculates the position data of the mark on the basis of the output mark signal. The processing unit 12b calculates a parameter representing a displacement of the substrate 4, on the basis of the output mark signal and the calculated position data of the mark. The control unit 12c controls the positioning of the substrate 4.

A given circuit pattern is drawn on the reticle 2. An underlying pattern and mark are formed on the substrate 4 by a preprocess. In this embodiment, the substrate 4 is an object on which a mark 11 is formed and which is positioned.

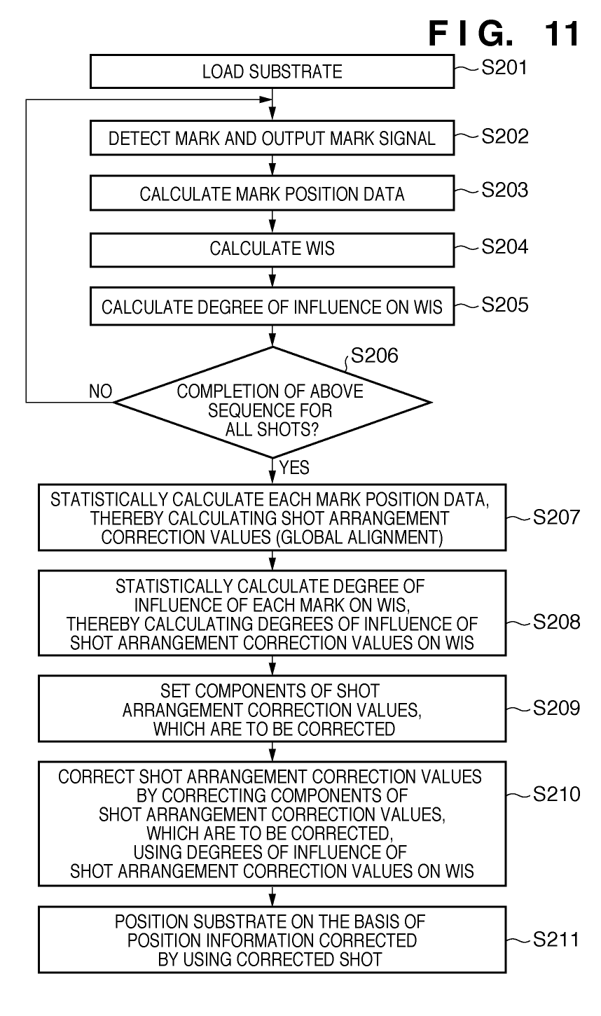

FIG. 10 is a flowchart illustrating a sequence of an alignment method according to this embodiment.

In step S101, the controller 12 loads a substrate 4 into the exposure apparatus 1. In step S102, the alignment detection optical system 7 detects the mark on the substrate 4 and outputs a mark signal.

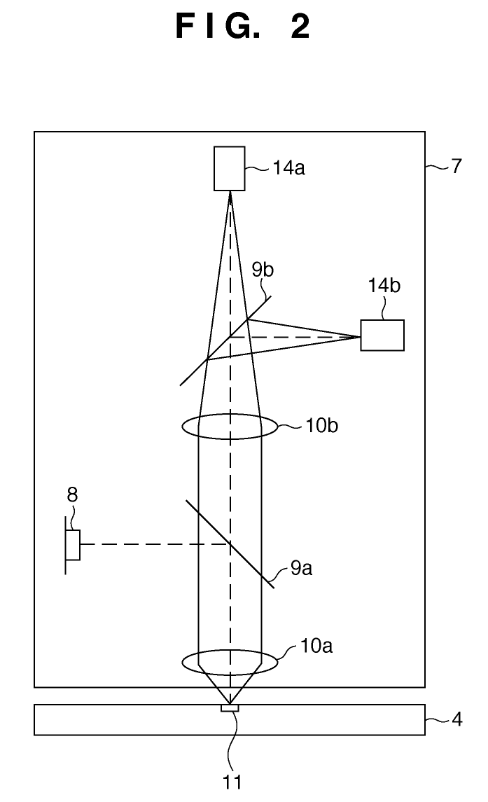

FIG. 2 is a view showing the main constituent elements of the alignment detection optical system 7. Illumination light from a light source 8 is reflected by a beam splitter 9a, propagates through a lens 10a, and illuminates the mark 11 on the substrate 4. The light diffracted by the mark 11 propagates through the lens 10a, the beam splitter 9a, and a lens 10b, and is divided by a beam splitter 9b. The divided light beams are received by CCD sensors 14a and 14b. Note that the mark 11 is enlarged at a magnification that allows the resolution to satisfy the measurement accuracy by the lenses 10a and 10b, and is imaged on the CCD sensors 14a and 14b. The CCD sensor 14a is used to measure a displacement of the mark 11 in the X direction. The CCD sensor 14b is used to measure a displacement of the mark 11 in the Y direction, and is set while being rotated through 90° about the optical axis. The measurement principles in both the X direction and Y direction are the same, so only position measurement in the X direction will be described below.

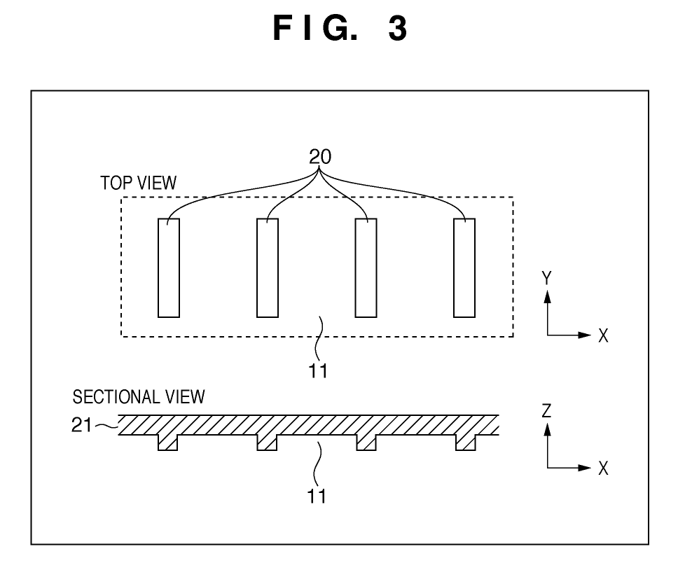

The mark 11 for use in position measurement will be explained first. In an example shown in FIG. 3, a plurality of strip-shaped marks 20 having predetermined dimensions in the measurement direction (X direction) and the non-measurement direction (Y direction) align themselves in the X direction at a predetermined interval. The mark 11 has a sectional structure recessed by an etching process, and is coated with a resist 21 on its surface.

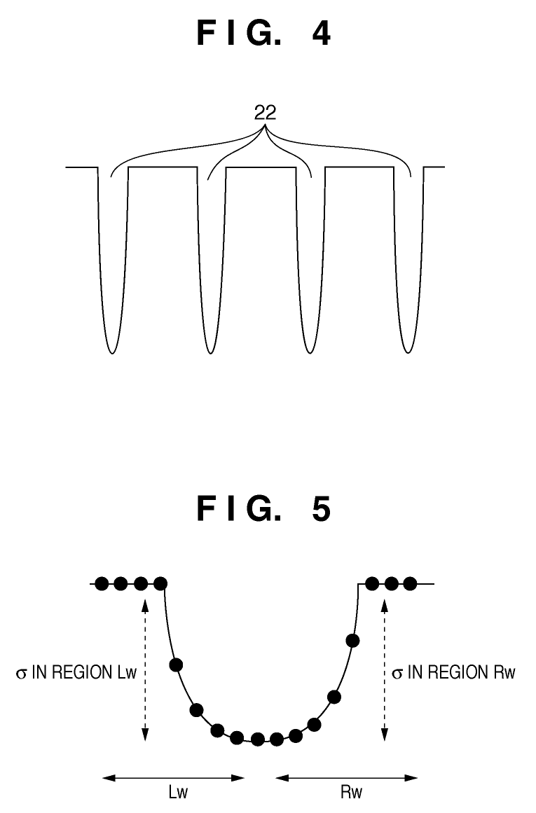

FIG. 4 shows an example of mark signals 22 when the CCD sensor 14a receives reflected light obtained by irradiating the plurality of marks 20 with illumination light. In step S103, the calculating unit 12a calculates the position data of the respective marks 20 on the basis of the corresponding mark signals 22 shown in FIG. 4. Finally, the average of the position data of the respective marks 20 is obtained, and is output as a mark position x.

In step S104, the processing unit 12b in the controller 12 calculates “a value quantitatively representing the features of the mark signal 22 (to be referred to as a feature value W hereinafter)”. The controller 12 calculates the feature value W in accordance with:

W=A×S^{a}×C^{b}×P^{c} (1)

where S is the asymmetry of the mark signal 22, C is the contrast of the mark signal 22, P is the shape of the mark signal 22, and A, a, b, and c are constants obtained from the relationship between the feature value and the WIS.

For “a right process region Rw (to be referred to as a right window hereinafter)” and “a left process region Lw (to be referred to as a left window hereinafter) of the mark signal 22 shown in FIG. 5, the value S representing the asymmetry of the mark signal 22 is defined by:

S=((θ in the region Rw)−(θ in the region Lw))/((θ in the region Rw)−(θ in the region Lw)) (2)

where θ is the standard deviation.

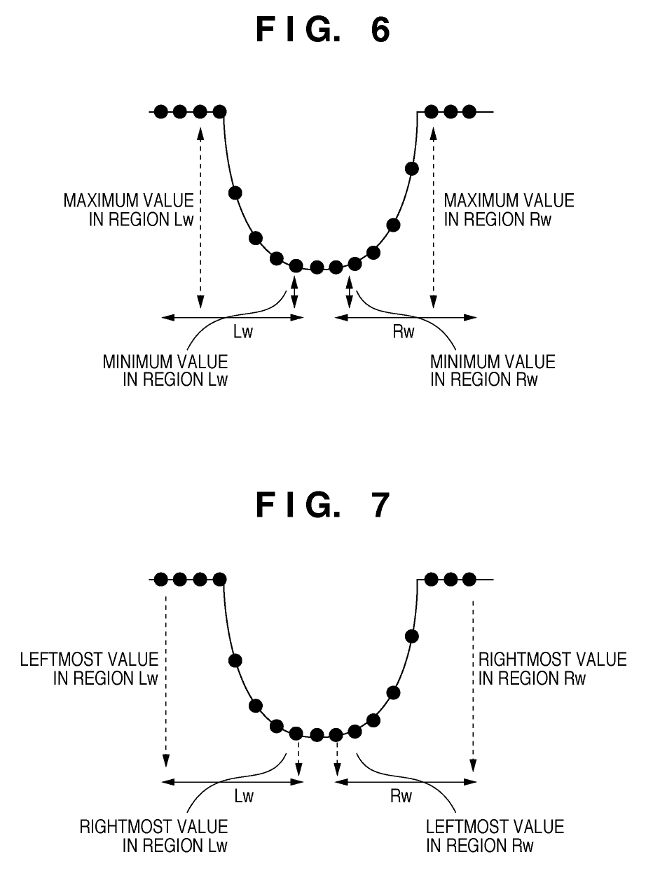

For the right window Rw and the left window Lw of the mark signal 22 shown in FIG. 6, the value C representing the contrast of the mark signal 22 is defined by:

C=((the contrast in the region Rw)+(the contrast in the region Lw))/2 (3)

where (the contrast in the region Rw or Lw)=((the maximum value in the region Rw or Lw)−(the minimum value in the region Rw or Lw))/((the maximum value in the region Rw or Lw)+(the minimum value in the region Rw or Lw))

For the right window Rw and the left window Lw of the mark signal 22 shown in FIG. 7, the value P representing the shape of the mark signal 22 is defined by:

P={((the rightmost value in the region Lw)+(the leftmost value in the region Rw))−((the leftmost value in the region Lw)+(the rightmost value in the region Rw))}/{((the rightmost value in the region Lw)+(the leftmost value in the region Rw) +((the leftmost value in the region Lw +(the rightmost value in the region Rw))} (4)

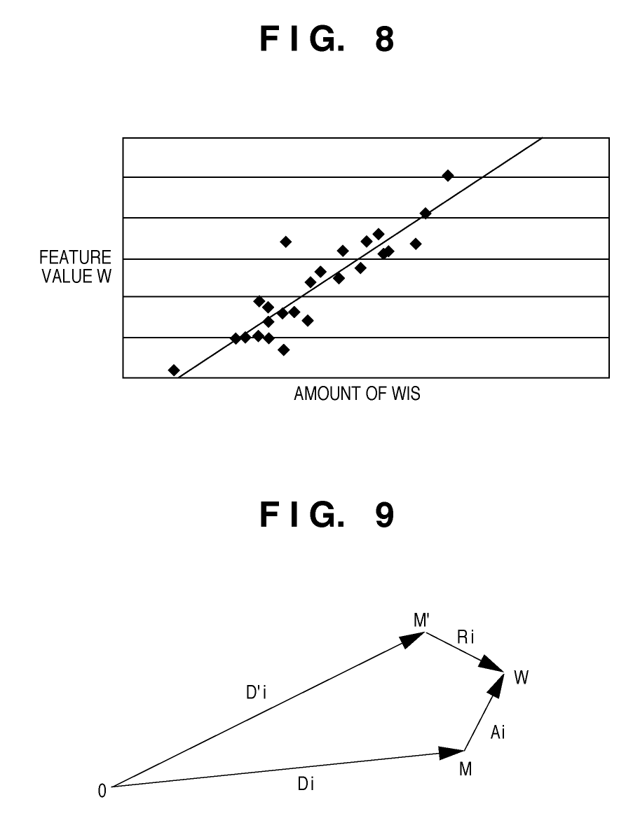

According to an experiment which uses a substrate 4 that actually suffers a WIS, the feature value W and the amount of WIS have a correlation such as that shown in FIG. 8. In other words, obtaining the feature value W makes it possible to detect ” the amount of WIS caused by the mark signal 22 (to be referred to as a degree of influence We on a WIS hereinafter). In step S105, the processing unit 12b in the controller 12 calculates, in accordance with the feature value W, the degree of influence We that the feature value W calculated in step S104 exerts on a displacement of the mark 11 calculated based on the calculation result obtained by the calculating unit 12a:

We=E×W (5)

where E is a transformation coefficient which represents the relationship between the feature value W and the degree of influence We on a WIS, and corresponds to the slope of the approximation line shown in FIG. 8.

In step S106, using the degree of influence We on a WIS calculated in step S104, the processing unit 12b corrects a detected mark position data x in accordance with:

X=x−We (6)

where X is the mark position data after correction, and x is the mark position data before correction.

Steps S102 to S106 are repeated for “several shots selected from all shots on the substrate 4 (to be referred to as sample shots hereinafter)”. During this time, the controller 12 sequentially calculates the mark position data x and feature value W in each sample shot, and corrects the mark position data x.

In step S108, the processing unit 12b statistically calculates the corrected mark position data X in each sample shot, and performs global alignment which calculates the overall shot arrangement correction values. The overall shot arrangement correction values are parameters representing a displacement of the substrate 4. Details of the global alignment has been proposed in Japanese Patent Laid-Open No. 63-232321, so only a global alignment calculation method will be simply explained below.

The amount of displacement of the substrate 4 can be described by parameters of a shift in the X direction Sx, a shift Sy in the Y direction, a rotation angle θx about the X-axis, a rotation angle θy about the Y-axis, a magnification Bx in the X direction, and a magnification By in the Y direction. A measurement value Ai in each sample shot is determined by:

$$Ai = [ \begin{matrix}xi \\ yi\end{matrix} ] \qquad ( 7 )$$

where i is the measurement shot number.

Coordinates Di of the mark design position in each sample shot is determined by:

$$Di = [ \begin{matrix}Xi \\ Yi\end{matrix} ] \qquad ( 8 )$$

In the global alignment, using the six parameters Sx, Sy, θx, θy, Bx, and By representing a displacement of the substrate described previously, a linear coordinate transformation D′i:

$${D}^{′} i = [ \begin{matrix}Bx & - θ y \\ θ x & By\end{matrix} ] Di + [ \begin{matrix}Sx \\ Sy\end{matrix} ] \qquad ( 9 )$$

Note that approximations cosθ=1 and sinθ=θ are used because θx and θy are very small values. Also, approximations such as θx*Bx=θx and θy*By=θy are used because Bx≈1 and By≈1.

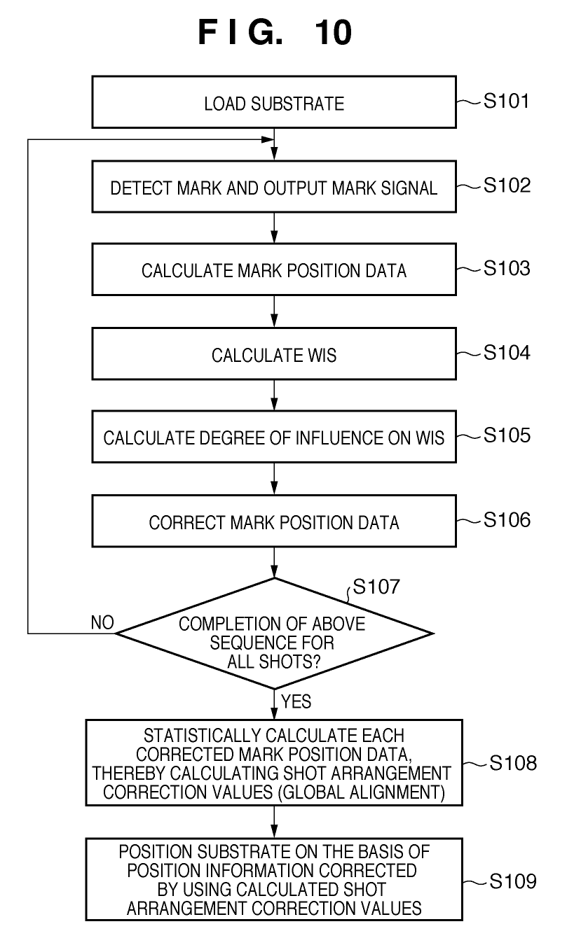

The mark 11 on the substrate lies at the position indicated by W in FIG. 9, which is displaced from a design position M by Ai. A displacement of the mark 11 on the substrate is rewritten as “Ri (to be referred to as a correction residue Ri hereinafter)” upon the coordinate transformation D′i. Note that FIG. 9 is a schematic diagram showing the coordinate transformation D′i and the correction residue Ri. The correction residue Ri is determined by:

Ri=(Di+Ai)−D′i (10)

The global alignment adopts the least-square method so that the correction residue Ri in each sample shot is minimized. That is, parameters Sx, Sy, θx, θy, Bx, and By that minimize a mean square V of the correction residue Ri are calculated. The mean square V is determined by:

$$\begin{matrix}\begin{matrix}V = \frac{1}{n} \sum {\vert Ri \vert}^{2} \\ = \frac{1}{n} {\sum }_{i = 1}^{i = n} {\vert [ \begin{matrix}xi \\ yi\end{matrix} ] - [ \begin{matrix}Bx - 1 & - θ y \\ θ x & By - 1\end{matrix} ] [ \begin{matrix}Xi \\ Yi\end{matrix} ] + [ \begin{matrix}Sx \\ Sy\end{matrix} ] \vert}^{2}\end{matrix} & ( 11 ) \\ [ \begin{matrix}δ V / δ Sx \\ δ V / δ Sy \\ δ V / δ Rx \\ δ V / δ Ry \\ δ V / δ Bx \\ δ V / δ By\end{matrix} ] = 0 & ( 12 )\end{matrix}$$

The parameters Sx, Sy, θx, θy, Bx, and By are obtained by substituting the position data (xi, yi) and design position data (Xi, Yi) of the mark 11 measured in each sample shot into equations (11) and (12). With the above-described operation, the calculation of the overall shot arrangement correction values by the global alignment is completed.

In step S109, the positioning controller 12c in the controller 12 controls the substrate stage 6 to position the substrate 4 on the basis of the position information of the substrate 4 corrected by using the six parameters Sx, Sy, θx, θy, Bx, and By calculated in step S108. The use of the alignment process according to this embodiment allows the removal of the influence of any WIS without optimizing an alignment parameter, thus attaining high-accuracy alignment. Note that the mark 11 according to this embodiment is not particularly limited to that shown in FIG. 3. Also, the transformation coefficient E for calculating the degree of influence on a WIS may be a predetermined constant coefficient or a coefficient which changes depending on the alignment method or the process of manufacturing a device.

### Second Embodiment

In the first embodiment, each mark position data is corrected by using the degree of influence We on a WIS first, and each corrected mark position data is statistically calculated, thereby calculating the shot arrangement correction values. In the second embodiment, each mark position data before correction is statistically calculated to calculate the shot arrangement correction values, and a degree of influence We of each mark 11 on a WIS is statistically calculated to calculate the degrees of influence of the shot arrangement correction values on a WIS. Using the degrees of influence of the shot arrangement correction values on a WIS, the shot arrangement correction values are corrected. The shot arrangement correction values are parameters representing a displacement of a substrate 4. The degrees of influence of the shot arrangement correction values on a WIS are the degrees of influence that a feature value W exerts on the parameters representing a displacement of the substrate 4.

The overall apparatus arrangement and operation are the same as in the first embodiment except for the alignment process. Only an alignment process according to this embodiment will be explained with reference to the flowchart shown in FIG. 11.

The sequence from when a substrate 4 is loaded until the degree of influence We of the mark 11 on a WIS is calculated in steps S201 to S205 are the same as in steps S101 to S105.

Steps S202 to S205 are repeated for each sample shot on the substrate 4. During this time, a controller 12 sequentially calculates the mark position data and feature value W in each sample shot. In step S207, a processing unit 12b in the controller 12 statistically calculates each mark position data calculated in step S203, thereby calculating the shot arrangement correction values.

In step S208, the processing unit 12b statistically calculates the degree of influence We of each mark 11 on a WIS calculated in step S205, thereby calculating “degrees of influence Wshot of the shot arrangement correction values on a WIS”. The degrees of influence Wshot of the shot arrangement correction values on a WIS are calculated by substituting:

$$Wei = [ \begin{matrix}Wexi \\ Weyi\end{matrix} ] \qquad ( 13 )$$

into equation (7) in the global alignment in step S108, and performing similar calculation as in equations (8) to (12), where Wexi and Weyi are the degrees of influence of each shot on a WIS. Therefore, the degrees of influence Wshot of the calculated shot arrangement correction values are WeSx, WeSy, Weθx, Weθy, WeBx, and WeBy. This makes it possible to transform the degrees of influence on a WIS into forms common to error components which are problematic in the manufacturing floor of a device. In step S209, the processing unit 12b sets components of the shot arrangement correction values, which are problematic in the manufacturing floor of a device and are to be corrected.

In step S210, the processing unit 12b corrects the shot arrangement correction values calculated in step S207, using the degrees of influence Wshot, on a WIS, of the shot arrangement correction values calculated in step S208. Then, we have:

SX=Sx−WeSx

SY=Sy−WeSy

θX=θx−Weσx

θY=θy−Weθy

BX=Bx−WeBx

BY=By−WeBy (14)

where SX, SY, θX, θY, BX, and BY are the corrected shot arrangement correction values.

If only shift components, for example, are set in step S209 as the components of the shot arrangement correction values which are problematic in the manufacturing floor of a device, the processing unit 12b calculates only the correction values SX and Sy in equations (14) in step S210. That is, the alignment process according to this embodiment can correct only a WIS attributed to a specific shot arrangement component, thus attaining high-accuracy alignment without exerting an influence on non-problematic other components.

In step S211, a control unit 12c in the controller 12 controls a substrate stage 6 to position the substrate 4 on the basis of the position information of the substrate 4 corrected by using only the correction values corrected in step S210, for example, the correction values Sx and Sy.

### Embodiment of Manufacture of Device

An embodiment of a method of manufacturing a device using the above-described exposure apparatus will be explained next.

Devices (e.g., a semiconductor integrated circuit device and liquid crystal display device) are manufactured by a step of exposing a substrate to radiant energy using the exposure apparatus according to the above-described embodiments, a step of developing the substrate exposed in the exposing step, and other known steps (e.g., etching, resist removing, dicing, bonding, and packaging steps) of processing the substrate developed in the developing step.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2008-014174, filed Jan. 24, 2008, which is hereby incorporated by reference herein in its entirety.

What is claimed is:

1. A positioning apparatus which positions an object using a mark formed on the object, the apparatus comprising:
a detector which detects the mark and outputs a mark signal; and
a controller,
said controller including
a calculating unit which calculates position data of the mark on the basis of the mark signal output from said detector,
a processing unit which calculates a parameter representing a displacement of the object, on the basis of the mark signal output from said detector and the position data of the mark calculated by said calculating unit, and
a positioning controller which controls the positioning of the object, on the basis of the position information of the object corrected by using the parameter calculated by said processing unit,
wherein said processing unit
calculates a feature value including a value representing an asymmetry of the mark signal, a value representing a contrast of the mark signal, and a value representing a shape of the mark signal,
calculates, on the basis of the calculated feature value, a degree of influence that the feature value exerts on a displacement of the mark calculated based on the calculation result obtained by said calculating unit,
corrects the calculated position data of the mark on the basis of the calculated degree of influence, and
statistically calculates the corrected position data of the mark, thereby calculating a parameter representing a displacement of the object.

2. The apparatus according to claim 1, wherein said processing unit calculates an amount of displacement of the mark corresponding to the calculated feature value using a coefficient representing a relationship between the feature value and the degree of influence, and corrects the calculated position data of the mark using the calculated amount of displacement.

3. A positioning apparatus which positions an object using a mark formed on the object, said apparatus comprising:
a detector which detects the mark and outputs a mark signal; and
a controller,
said controller including
a calculating unit which calculates position data of the mark on the basis of the mark signal output from said detector,
a processing unit which calculates a parameter representing a displacement of the object, on the basis of the mark signal output from said detector and the position data of the mark calculated by said calculating unit, and
a positioning controller which controls the positioning of the object,
wherein said processing unit
calculates a feature value including a value representing an asymmetry of the mark signal, a value representing a contrast of the mark signal, and a value representing a shape of the mark signal,
calculates, on the basis of the calculated feature value, a degree of influence that the feature value exerts on a displacement of the mark calculated based on the calculation result obtained by said calculating unit,
statistically calculates the position data of the mark calculated by said calculating unit, thereby calculating a parameter representing a displacement of the object,
statistically calculates the calculated degree of influence, thereby calculating a degree of influence that the feature value exerts on the parameter representing the displacement of the object, and
corrects the calculated parameter using the calculated degree of influence exerted on the parameter, and
said positioning controller controls the positioning of the object, on the basis of the position information of the object corrected by using the parameter corrected by said processing unit.

4. The apparatus according to claim 3, wherein the feature value includes at least one of a value representing an asymmetry of the mark signal, a value representing a contrast of the mark signal, and a value representing a shape of the mark signal.

5. An exposure apparatus which exposes a substrate, the exposure apparatus comprising:
a substrate stage configured to hold the substrate and move; and
a positioning apparatus configured to position the substrate using a mark formed on the substrate,
said positioning apparatus comprising
a detector configured to detect the mark and output a mark signal, and
a controller,
said controller including
a calculating unit configured to calculate position data of the mark on the basis of the mark signal output from said detector,
a processing unit configured to calculate a parameter representing a displacement of the substrate, on the basis of the mark signal output from said detector and the position data of the mark calculated by said calculating unit, and
a positioning controller configured to control said substrate stage to position the substrate, on the basis of the position information of the substrate corrected by using the parameter calculated by said processing unit,
wherein said processing unit
calculates a feature value including a value representing an asymmetry of the mark signal, a value representing a contrast of the mark signal, and a value representing a shape of the mark signal,
calculates, on the basis of the calculated feature value, a degree of influence that the feature value exerts on a displacement of the mark calculated based on the calculation result obtained by said calculating unit,
corrects the calculated position data of the mark on the basis of the calculated degree of influence, and
statistically calculates the corrected position data of the mark, thereby calculating a parameter representing a displacement of the substrate.

6. An exposure apparatus which exposes a substrate, the exposure apparatus comprising:
a substrate stage configured to hold the substrate and move; and
a positioning apparatus configured to position the substrate using a mark formed on the substrate,
said positioning apparatus comprising
a detector configured to detect the mark and output a mark signal, and
a controller,
said controller including
a calculating unit configured to calculate position data of the mark on the basis of the mark signal output from said detector,
a processing unit configured to calculate a parameter representing a displacement of the substrate, on the basis of the mark signal output from said detector and the calculated position data of the mark, and
a positioning controller configured to control said substrate stage to position the substrate, on the basis of the position information of the substrate corrected by using the parameter corrected by said processing unit,
wherein said processing unit
calculates a feature value including a value representing an asymmetry of the mark signal, a value representing a contrast of the mark signal, and a value representing a shape of the mark signal,
calculates, on the basis of the calculated feature value, a degree of influence that the feature value exerts on a displacement of the mark calculated based on the calculation result obtained by said calculating unit,
statistically calculates the position data of the mark calculated by said calculating unit, thereby calculating a parameter representing a displacement of the substrate,
statistically calculates the calculated degree of influence, thereby calculating a degree of influence that the feature value exerts on the parameter representing the displacement of the substrate, and
corrects the calculated parameter using the calculated degree of influence exerted on the parameter.

7. A method of manufacturing a device, the method comprising:
exposing a substrate to radiant energy using an exposure apparatus;
developing the exposed substrate; and
processing the developed substrate to manufacture the device,
wherein the exposure apparatus comprises
a substrate stage configured to hold the substrate and move, and
a positioning apparatus configured to position the substrate using a mark formed on the substrate,
the positioning apparatus comprises
a detector configured to detect the mark and output a mark signal, and
a controller,
the controller includes
a calculating unit configured to calculate position data of the mark on the basis of the mark signal output from the detector,
a processing unit configured to calculate a parameter representing a displacement of the substrate, on the basis of the mark signal output from the detector and the position data of the mark calculated by the calculating unit, and
a positioning controller configured to control the substrate stage to position the substrate, on the basis of the position information of the substrate corrected by using the parameter calculated by the processing unit, and
the processing unit
calculates a feature value including a value representing an asymmetry of the mark signal, a value representing a contrast of the mark signal, and a value representing a shape of the mark signal,
calculates, on the basis of the calculated feature value, a degree of influence that the feature value exerts on a displacement of the mark calculated based on the calculation result obtained by the calculating unit,
corrects the calculated position data of the mark on the basis of the calculated degree of influence, and
statistically calculates the corrected position data of the mark, thereby calculating a parameter representing a displacement of the substrate.

8. A method of manufacturing a device, the method comprising:
exposing a substrate to radiant energy using an exposure apparatus;
developing the exposed substrate; and
processing the developed substrate to manufacture the device,
wherein the exposure apparatus comprises
a substrate stage configured to hold the substrate and move, and
a positioning apparatus configured to position the substrate using a mark formed on the substrate,
the positioning apparatus comprises
a detector configured to detect the mark and output a mark signal, and
a controller,
the controller includes
a calculating unit configured to calculate position data of the mark on the basis of the mark signal output from the detector,
a processing unit configured to calculate a parameter representing a displacement of the substrate, on the basis of the mark signal output from the detector and the calculated position data of the mark, and
a positioning controller configured to control the substrate stage to position the substrate, on the basis of the position information of the substrate corrected by using the parameter corrected by the processing unit, and
the processing unit
calculates a feature value including a value representing an asymmetry of the mark signal, a value representing a contrast of the mark signal, and a value representing a shape of the mark signal,
calculates, on the basis of the calculated feature value, a degree of influence that the feature value exerts on a displacement of the mark calculated based on the calculation result obtained by the calculating unit,
statistically calculates the position data of the mark calculated by the calculating unit, thereby calculating a parameter representing a displacement of the substrate,
statistically calculates the calculated degree of influence, thereby calculating a degree of influence that the feature value exerts on the parameter representing the displacement of the substrate, and
corrects the calculated parameter using the calculated degree of influence exerted on the parameter.
